(19) United States
(12) Patent Application Publication
(10) Pub. No.: US 2006/0175012 A1
(43) Pub. Date: Aug. 10, 2006

(54) Semiconductor fabrication equipment and method for controlling pressure

(76) Inventor: Beung-Keun Lee, Hwaseong-si (KR)

Correspondence Address: VOLENTINE FRANCOS, & WHITT PLLC, ONE FREEDOM SQUARE, 11951 FREEDOM DRIVE SUITE 1260, RESTON, VA, 20190, US

(21) Appl. No.: 11/347,178

(22) Filed: Feb. 6, 2006

(30) Foreign Application Priority Data
Feb. 7, 2005 (KR) 2005-11293

(51) Int. Cl. H01L 21/306; H01L 21/302; C23C 16/00; H01L 21/31

(52) U.S. Cl. 156/345.29; 156/345.24; 118/715; 438/689; 438/758

(57) ABSTRACT

Provided are semiconductor fabrication equipment and a related method of controlling pressure in a process chamber associated with the equipment. Multiple connected vacuum lines, each having a controllable valve, are used to exhaust gas from the process chamber.

### BACKGROUND OF THE INVENTION

1. Field of the Invention

Embodiments of the invention relate to semiconductor fabrication equipment. More particularly, embodiments of the invention relate to semiconductor fabrication equipment and an associated method of controlling the pressure within the equipment.

2. Description of the Related Art

Contemporary semiconductor devices are fabricated using a complex sequence of processes. This complex sequence may include multiple processes related to, for example, etching, ashing, chemical vapor deposition, and metal deposition, etc. Nearly all of these fabrication processes are performed within the controlled environs of a specialized process chamber. One or more process gases are supplied to the process chamber as part of many of the conventional fabrication processes. Indeed, the process gases are commonly converted into a plasma or a high-temperature gas within the process chamber during fabrication processes in order to produce a desired reaction with the silicon wafer being processed. In this manner constituent material layers are commonly formed in the silicon wafer.

In such processes, the pressure and temperature provided by the process chamber are important process conditions. This is particularly true for certain fabrication processes, such as those used to deposit a material film on the wafer. Stable process chamber pressure is required to ensure uniform deposition of the film.

FIG. 1 is a schematic view of a pressure-adjusting system commonly associated with conventional semiconductor fabrication equipment.

Referring to FIG. 1, the conventional pressure-adjusting system includes a vacuum pump 13 connected to a process chamber 11. As such, vacuum pump 13 may pump gas from process chamber 11 via vacuum line 15 to create a high-vacuum state within process chamber 11. A throttle valve 20 is commonly provided along the length of vacuum line 15, and is configured to controllably adjust the internal pressure of process chamber 11. A controller 22 is operatively connected to throttle valve 20 to control the opening and closing operations of throttle valve 20.

Unfortunately, the conventional pressure-adjusting system using throttle valve 20 suffers form a number of problems. For example, a great deal of reactive byproducts are produced by the processes routinely performed in process chamber 11. Some of these byproducts may be accumulated on the inner surfaces of throttle valve 20 as they are exhausted through vacuum line 15. In fact, the opening and closing operations of throttle valve 20 often cause byproduct buildup on several portions of the inner surface of throttle valve 20. The accumulation byproducts may build up to the point where proper operation of throttle valve 20. Such a failure leads to inaccurate pressure development and/or maintenance within process chamber 11.

Even where proper operation of throttle valve 20 is maintained, byproduct accumulation may restrict the flow of fluids (e.g., gases) through throttle valve 20, thereby making it difficult to accurately adjust the pressure of process chamber 11. As a result, preventive maintenance of the conventional throttle valve must be performed more frequently than other valves associated with the semiconductor fabrication equipment, and increased maintenance down time degrades the operating efficiency of the equipment.

### SUMMARY OF THE INVENTION

Embodiments of the invention provide semiconductor fabrication equipment and a related method of controlling the internal pressure of a process chamber amongst the equipment in which it is possible to conveniently adjust the internal pressure of the process chamber in a stepwise manner without using a conventional throttle valve that tends to fail frequently and thus requires frequent maintenance.

In one embodiment, the invention provides semiconductor fabrication equipment comprising; a process chamber and a vacuum exhaust unit adapted to exhaust gas from the process chamber to adjust an internal pressure of the process chamber between a first set value and a second set value higher than the first set value. The vacuum exhaust unit comprises; a vacuum pump, a first vacuum line having a first internal diameter and connected between the vacuum pump and the process chamber, a first valve mounted on the first vacuum line, a second vacuum line having a second internal diameter less than the first internal diameter and operatively connected to bypass the first valve and exhaust gas from the process chamber, a second valve mounted on the second vacuum line, and a controller configured to control opening and/or closing of the first and second valves in accordance with the first set value or the second set value.

In another embodiment, the invention provides a method for adjusting pressure within a process chamber adapted for use within semiconductor fabrication equipment, the method comprising; (a) maintaining pressure within the process chamber at a first set value, and (b) maintaining pressure within the process chamber at a second set value. By operation of a controller, gas is exhausted from the process chamber through at least a main vacuum line directly connected to the process chamber and having a main valve connected to the controller during (a), gas is exhausted from the process chamber through only at least one bypass vacuum line operatively connected to the process chamber during (b), the at least one bypass vacuum line having a bypass valve connected to the controller.

In yet another embodiment, the invention provides a method of adjusting pressure within a process chamber adapted for use within semiconductor fabrication equipment, the method comprising; by means of a controller, maintaining different pressure set values within the process chamber by variously exhausting gas from the process chamber through a plurality of vacuum lines, each one of the vacuum lines having a different internal diameter and being opened or closed by a corresponding valve connected to the controller.

### BRIEF DESCRIPTION OF THE DRAWINGS

Several embodiments of the invention will be described with reference to the accompanying drawings. In the drawings:

FIG. 1 is a schematic view of a pressure-adjusting system in a conventional semiconductor fabrication equipment;

FIG. 2 is a schematic view of a semiconductor fabrication equipment according to a first embodiment of the present invention;

FIG. 3 is a table illustrating the controlled conditions of valves illustrated in FIG. 2;

FIG. 4 is a flow chart comparing a pressure-adjusting process according to the present invention with a conventional temperature-adjusting process using a throttle valve;

FIGS. 5A and 5B are schematic views illustrating modified installation of a second vacuum line illustrated in FIG. 2;

FIG. 6 is a schematic view of a semiconductor fabrication equipment according to a second embodiment of the present invention; and

FIG. 7 is a table illustrating the controlled conditions of valves illustrated in FIG. 6.

### DESCRIPTION OF EXEMPLARY EMBODIMENTS

Reference will now be made in some additional detail to several embodiments of the invention. However, the invention is not limited to only these embodiments. Rather, the embodiments are presented as teaching examples. Throughout the specification and accompanying drawings, like reference numerals indicate like or similar elements.

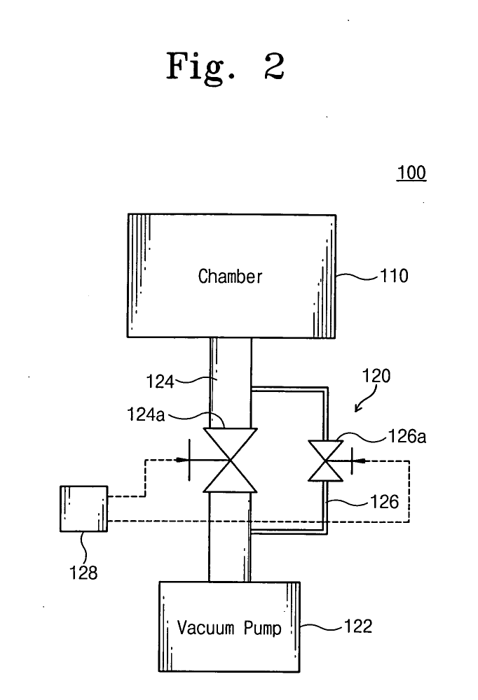

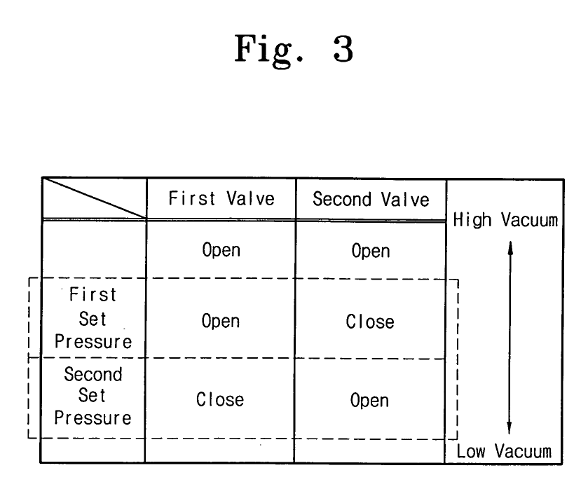

FIG. 2 is a schematic view of a semiconductor fabrication equipment according to a first embodiment of the invention. FIG. 3 is a table illustrating the controlled conditions the valves illustrated in FIG. 2.

Referring to FIG. 2, semiconductor fabrication equipment 100 comprises a process chamber 110 and a vacuum exhaust unit 120. Vacuum exhaust unit 120 is adapted to exhaust gas from process chamber 110 to thereby adjust the internal pressure of process chamber 110. In one embodiment, pressure within process chamber 110 is adjusted by a first set value and/or a second set value having a higher pressure setting than the first set value.

In the illustrated example, vacuum exhaust unit 120 comprises a vacuum pump 122, a first vacuum line 124, a second vacuum line 126, and a controller 128. Vacuum pump 122 and process chamber 110 are connected by first vacuum line 124. First valve 124a is installed on first vacuum line 124. In one embodiment, second vacuum line 126 has a smaller internal diameter than first vacuum line 124, and is configured to bypass first value 124a. A second valve 126a is installed on second vacuum line 126.

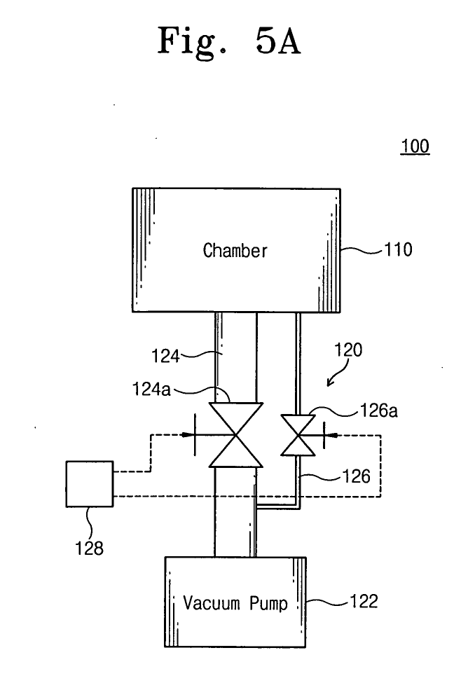

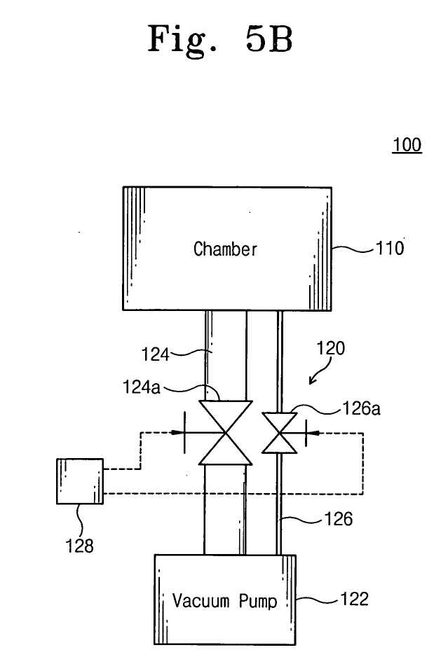

Alternatively, as illustrated in FIG. 5A, one end of second vacuum line 126 may be directly connected to process chamber 110 and the other end connected to first vacuum line 124 between first valve 124a and vacuum pump 122. Further alternatively, as illustrated in FIG. 5B, second vacuum line 126 may be directly connected between process chamber 110 and vacuum pump 122. In any one of these design alternatives, controller 128 is independently connected to first valve 124a and second valve 126a and serves to open and close the valves to regulate pressure in process chamber 110. In this manner, vacuum exhaust unit 120 is adapted to adjust the internal pressure of process chamber 110 by opening and/or closing first and second valves 124a and 126a.

Referring to FIGS. 2 and 3, in order to develop and/or maintain the internal pressure within process chamber 110 at a first set value, gas from within process chamber 110 is exhausted through first vacuum line 124. Similarly, in order to develop and/or maintain the internal pressure of process chamber 110 at a second set value, gas from within process chamber 110 is exhausted through second vacuum line 126.

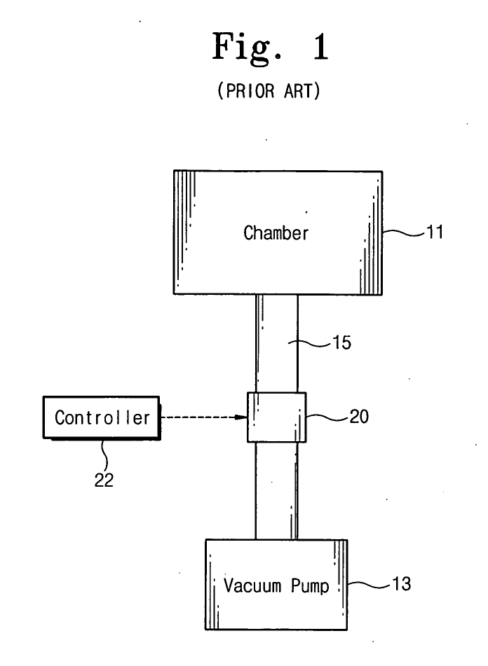

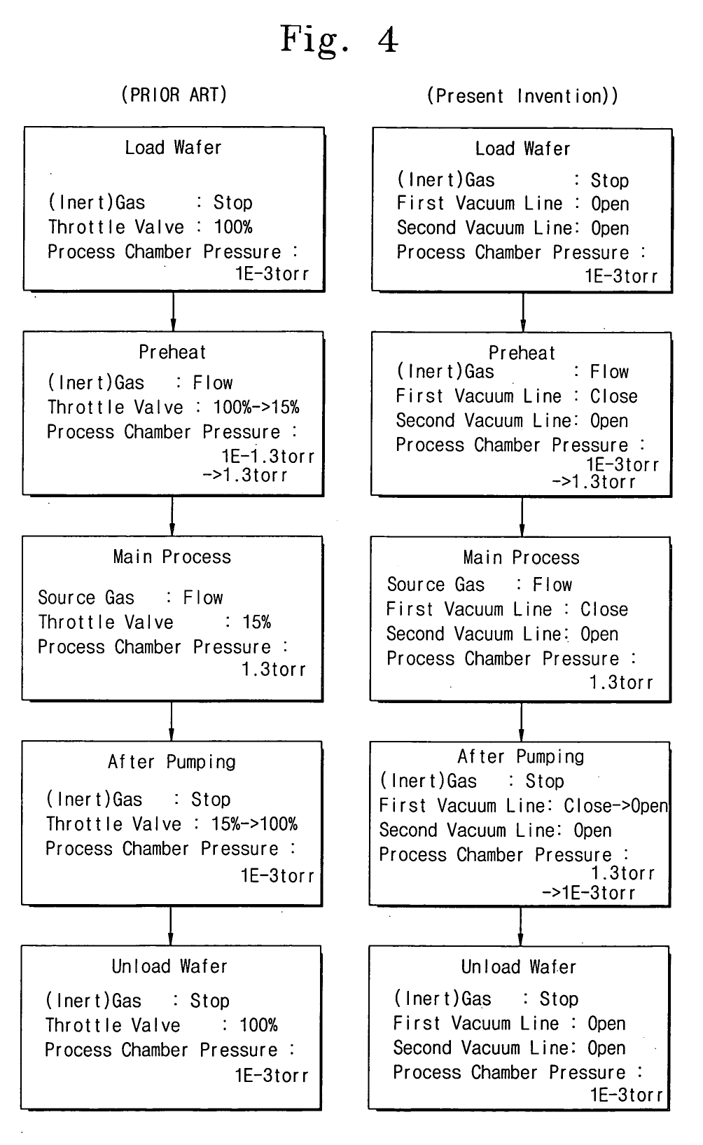

FIG. 4 is a flow chart comparing exemplary pressure-adjusting methods; one in accordance with an embodiment of the invention (hereafter referred to as the “inventive process” for the sake of brevity), and another in accordance with a conventional pressure-adjusting process using the throttle valve described above in relation to FIG. 1.

Referring collectively to FIGS. 1 through 4, both the conventional and inventive processes begin in a “Load Wafer” state. An initial pressure within a process chamber is assumed to be around 1E-3 torr for both cases.

During a subsequent “Preheat” state, the conventional method changes the opening rate of throttle valve 20 from 100% to around 15% in order increase pressure within process chamber 11 from 1E-3 torr to 1.3 torr as (e.g.) an inert gas is introduced into process chamber 11.

With pressure stabilized at 1.3 torr, a “Main Process” state is entered and (e.g.,) a source gas is introduced into process chamber 11 along with the inert gas. Note that the continued introduction of gases into process chamber 11 will require some countervailing operation of vacuum pump 13 to maintain stable pressure. The opening rate of throttle valve 20 is typically maintained at 15% throughout the pumping operation.

Following completion of the Main Process, the flow of gas is stopped and the throttle valve reopened to 100% to return the chamber to a pressure of 1E-3 torr during an “After Pumping” state. Thereafter, the wafer being processed may be removed from process chamber 11 in an “Unload Wafer” state.

In contrast, the inventive method begins the “Load Wafer” state with both first and second valves, 124a and 126a, opened. During the “Preheat” state, process chamber 110 is exhausted through only second vacuum line 126, as first vacuum line 124 is closed by first valve 124a. Second vacuum line 126 is used to maintain a desired pressure (e.g., 1.3 torr) within process chamber 110 throughout the “Main Process” state. Then during the “After Pumping” state, first valve 124a is opened to exhaust the reactive byproducts and return process chamber 110 to its initial pressure. Thereafter, the wafer being processed may be removed from process chamber 110 during the “Unload Wafer” state.

In the foregoing example, it is assumed that the internal diameter ratio of first vacuum line 124 to second vacuum line 126 is about 100 to 15. For example, assuming a first vacuum line 124 having an internal diameter of 300 mm, a second vacuum line 126 would be chosen with an internal diameter of about 45 mm.

The foregoing example is particularly suitable for a case where process chamber 110 needs only two set pressures. However, in a case where process chamber 110 needs three or more set pressures, a plurality of variously-sized, second vacuum lines 126 may be installed in addition to first (main) vacuum line 124. In such cases, controller 128 controls the opening and/or closing of the respective valves installed on the plurality of vacuum lines, such that gas within process chamber 110 is properly exhausted through at least one of the vacuum lines.

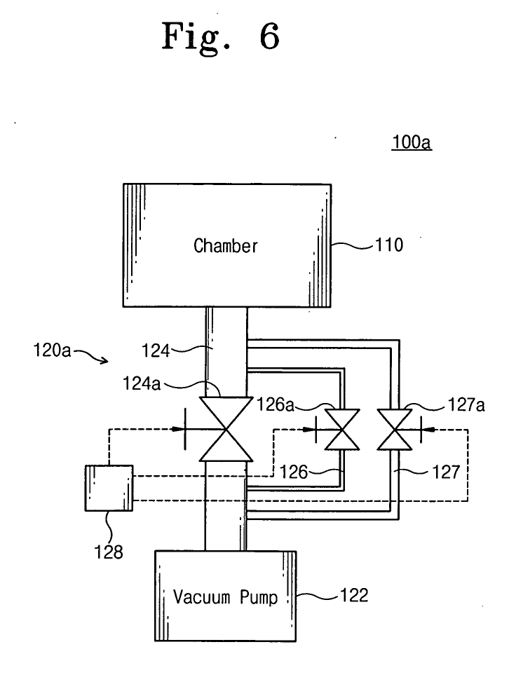

FIG. 6 is a schematic view of semiconductor fabrication equipment according to another embodiment of the invention.

Referring to FIG. 6, the semiconductor fabrication equipment comprises process chamber 110 and a vacuum exhaust unit 120a having a substantially similar structure and functions as those described in relation to FIG. 2. However, in this embodiment, process chamber 110 is assumed to require three set pressures. For this purpose, vacuum exhaust unit 120a comprises a first vacuum line 124 and two “bypass” vacuum lines, that is, a second vacuum line 126 and a third vacuum line 127. Second valve 126a and third valve 127a are installed on a second vacuum line 126 and a third vacuum line 127, respectively. The second and third vacuum lines 126 and 127 have different internal diameters.

By collectively controlling the operation of all three valves with controller 128, vacuum exhaust unit 120a may establish up to seven different set values through a plurality of states. Alternatively, any reasonable number of vacuum lines and valves may be used to accurately develop and maintain multiple pressure set points.

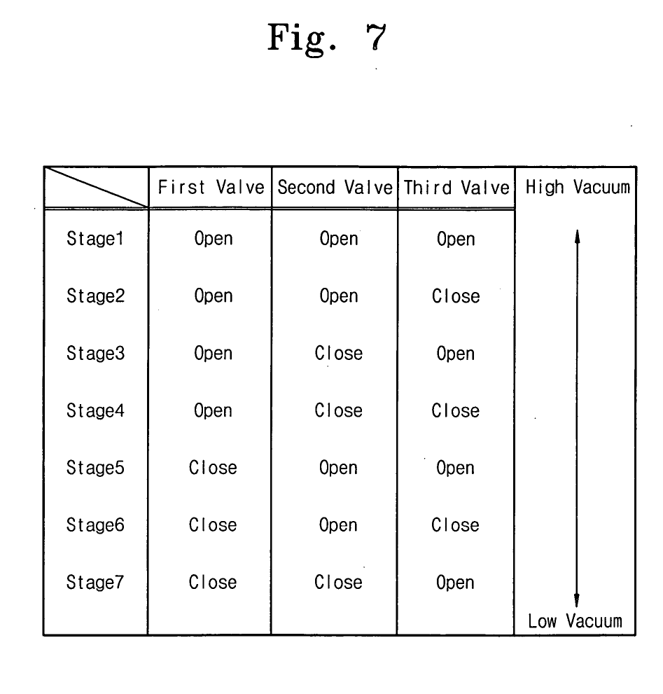

For example, the table of FIG. 7 illustrates the controlled conditions for the valves illustrated in FIG. 6.

Referring to FIG. 7, controller 128 controls the opening or closing of first, second and third valves 124a, 126a and 127a, such that gas within process chamber 110 is exhausted through at least one of vacuum lines 124, 126 and 127. In this manner, vacuum exhaust unit 120a may adjust the pressure within process chamber 110 to seven or fewer values by selectively opening or closing the three vacuum lines without using a throttle valve. As illustrated in FIG. 7, stage 1 corresponds to the highest degree of vacuum in process chamber 110, and a stage 7 corresponds to the lowest degree of vacuum. As further illustrated in FIG. 7, the vacuum exhaust unit 120a controls the opening or closing of first, second and third valves 124a, 126a and 127a according to a set pressure value required by process chamber 110.

While the conventional art adjusts the pressure within process chamber 11 by changing the opening rate of throttle valve 20, embodiments of the present invention adjust the pressure within process chamber 110 by selectively opening and/or closing the vacuum lines having different internal diameters.

Thus, in one aspect, embodiments of the invention may be characterized by the inclusion of at least one second (bypass) vacuum line in addition to a first (main) vacuum line, wherein at least one second vacuum line(s) have a smaller internal diameter than the first vacuum line.

As described above, the present invention adjusts the internal pressure of the process chamber by selectively opening or closing the vacuum lines, thereby making it possible to set the internal pressure of the process chamber to various values. Also, because gases are typically supplied through different routes, the corresponding nozzles can be less contaminated and contaminant due to reaction of the different gases may be reduced. Furthermore, it is possible to reduce the time required for exhaust gases from the process chamber.

It will be apparent to those skilled in the art that various modifications and variations can be made to the foregoing embodiments. Thus, it is intended that the present invention covers the modifications and variations of this invention provided they come within the scope of the appended claims and their equivalents.

What is claimed is:

1. Semiconductor fabrication equipment comprising:
a process chamber, and a vacuum exhaust unit adapted to exhaust gas from the process chamber to adjust an internal pressure of the process chamber between a first set value and a second set value higher than the first set value,
the vacuum exhaust unit comprising:
a vacuum pump;
a first vacuum line having a first internal diameter and connected between the vacuum pump and the process chamber;
a first valve mounted on the first vacuum line;
a second vacuum line having a second internal diameter less than the first internal diameter and operatively connected to bypass the first valve and exhaust gas from the process chamber;
a second valve mounted on the second vacuum line; and,
a controller configured to control opening and/or closing of the first and second valves in accordance with the first set value or the second set value.

2. The equipment of claim 1, wherein the second vacuum line is connected to first and second points along the length of the first vacuum line to bypass the first valve.

3. The equipment of claim 1, wherein one end of the second vacuum line is directly connected to the process chamber and the other end of the second vacuum line is connected to a point along the first vacuum line between the vacuum pump and the first valve to bypass the first valve.

4. The equipment of claim 1, wherein one end of the second vacuum line is directly connected to the process chamber and the other end of the second vacuum line is directly connected to the vacuum pump to bypass the first valve.

5. The equipment of claim 2, wherein the process chamber is adapted to operate in first and second states, and wherein gas is exhausted from the process chamber through at least the first vacuum line during the first state, and gas is exhausted from the process chamber through only the second vacuum line during the second state.

6. The equipment of claim 1, wherein the first and second set values correspond to the first and second states.

7. The equipment of claim 1, wherein the second vacuum line comprises multiple second vacuum lines each having a progressively smaller internal diameter, and each having a corresponding valve mounted thereon.

8. A method for adjusting pressure within a process chamber adapted for use within semiconductor fabrication equipment, the method comprising:
(a) maintaining pressure within the process chamber at a first set value; and
(b) maintaining pressure within the process chamber at a second set value,
wherein by operation of a controller, gas is exhausted from the process chamber through at least a main vacuum line directly connected to the process chamber and having a main valve connected to the controller during (a); and,
wherein by operation of the controller, gas is exhausted from the process chamber through only at least one bypass vacuum line operatively connected to the process chamber during (b), the at least one bypass vacuum line having a bypass valve connected to the controller.

9. The method of claim 8, wherein the at least one bypass vacuum line has a smaller internal diameter than the main vacuum line.

10. The method of claim 9, wherein the at least one bypass vacuum line is connected to first and second points along the length of the main vacuum line to bypass the first valve.

11. The method of claim 9, wherein one end of the bypass vacuum line is directly connected to the process chamber and the other end of the bypass vacuum line is connected to a point along the main vacuum line between a vacuum pump and the first valve to bypass the first valve.

12. The method of claim 9, wherein one end of the bypass vacuum line is directly connected to the process chamber and the other end of the bypass vacuum line is directly connected to a vacuum pump to bypass the first valve.

13. A method for adjusting pressure within a process chamber adapted for use within semiconductor fabrication equipment, the method comprising:
by means of a controller, maintaining different pressure set values within the process chamber by variously exhausting gas from the process chamber through a plurality of vacuum lines, each one of the vacuum lines having a different internal diameter and being opened or closed by a corresponding valve connected to the controller.

14. The method of claim 14, wherein each one of the plurality of vacuum lines is operatively connected to a single vacuum pump.

15. The method of claim 14, wherein the plurality of vacuum lines comprises:
a main vacuum line having a largest internal diameter directly connected between the process chamber and the vacuum pump; and,
at least one bypass vacuum line having a diameter less than the main vacuum line and operatively connected to valve on the main vacuum line and exhaust gas from the process chamber.

16. The method of claim 15, wherein the bypass vacuum line is connected to first and second points along the length of the main vacuum line around the valve on the main vacuum line.

17. The method of claim 15, wherein one end of the bypass vacuum line is directly connected to the process chamber and the other end of the bypass vacuum line is connected to a point along the main vacuum line between the vacuum pump and the valve on the main vacuum line.

18. The method of claim 15, wherein one end of the bypass vacuum line is directly connected to the process chamber and the other end of the bypass vacuum line is directly connected to the vacuum pump.
